(19) United States
(12) Patent Application Publication
(10) Pub. No.: US 2007/0126074 A1
(43) Pub. Date: Jun. 7, 2007

(54) Optical sheet

(75) Inventors: Shih-Yi Chuang, Kaohsiung (TW); Chao-Yi Tsai, Kaohsiung (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Eternal Chemical Co., Ltd., Kaohsiung (TW)

(21) Appl. No.: 11/601,350

(22) Filed: Nov. 16, 2006

(30) Foreign Application Priority Data
Dec. 7, 2005 (TW) 094221279

(51) Int. Cl. H01L 31/0232

(52) U.S. Cl. 257/432

(57) ABSTRACT

An optical sheet includes an substrate having a first surface and a second surface opposite to the first surface, a light gathering layer formed on the first surface of the substrate, and an light diffusion layer formed on the second surface of the substrate. The light diffusion layer includes a polymeric resin having a plurality of bubbles mixed therein. The optical sheet of the subject invention can be used in LCDs as a photo-diffusive brightness enhancement film.

### BACKGROUND OF THE INVENTION

1. Field of the Invention

This invention relates to an optical sheet, more particularly to an optical sheet including a substrate formed with a light gathering layer and a light diffusion layer on two opposite sides thereof, respectively.

2. Description of the Related Art

Many approaches have been proposed to increase the range of viewing angles or brightness of a liquid crystal display (LCD). For example, it has been attempted to increase the number of lamps in the light source of the LCD so as to enhance brightness of a display panel of the LCD. However, an increase in the number of lamps will cause a waste of energy and generate a considerable amount of heat. The generated heat will accumulate inside the LCD, thereby deteriorating electronic components in the LCD and shortening the service life of the LCD.

Recently, the brightness of a display panel of the LCD can be enhanced using a brightness enhancement film or a prism film.

The brightness enhancement film traditionally can be manufactured by applying a layer of curable resin, such as acrylic resin, on a polyester substrate, and then patterning the layer of curable resin through imprinting or irradiating with a UV light so as to form microstructures on a surface of the layer of curable resin.

WO 96/23649 discloses an improved method for making a brightness enhancement film. Referring to FIG. 1, the brightness enhancement film 1 obtained from WO 96/23649 includes a substrate 11 and a layer of oligomeric resin 12 formed on the substrate 11. The substrate 11 has a smooth surface 111 opposite to the layer of oligomeric resin 12. The layer of oligomeric resin 12 is formed with a microstructure in the form of prisms 121. Subsequently, the microstructure is subjected to heat treatment so as to reduce deformation thereof.

Although the brightness of the display panel of the LCD can be enhanced using a brightness enhancement film, uneven light beams through the display panel remains a problem. Hence, there is a need in the art to provide a dual-function optical sheet which can enhance the brightness as well as the uniformity of light through the display panel.

### SUMMARY OF THE INVENTION

Therefore, the object of the present invention is to provide an optical sheet that includes a light gathering layer and a light diffusion layer so as to enhance the brightness as well as the uniformity of light when applied to the LCDs as a photo-diffusive brightness enhancement film.

According to this invention, an optical sheet includes a substrate having a first surface and a second surface opposite to the first surface, a light gathering layer formed on the first surface of the substrate, and an light diffusion layer formed on the second surface of the substrate. The light diffusion layer includes a polymeric resin having a plurality of bubbles mixed therein.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a fragmentary side view to illustrate a conventional optical sheet;

FIG. 2 is a fragmentary sectional view to illustrate the preferred embodiment of an optical sheet according to the present invention; and

FIGS. 3 to 7 are fragmentary sectional views to illustrate various structural modifications of the preferred embodiment of FIG. 2.

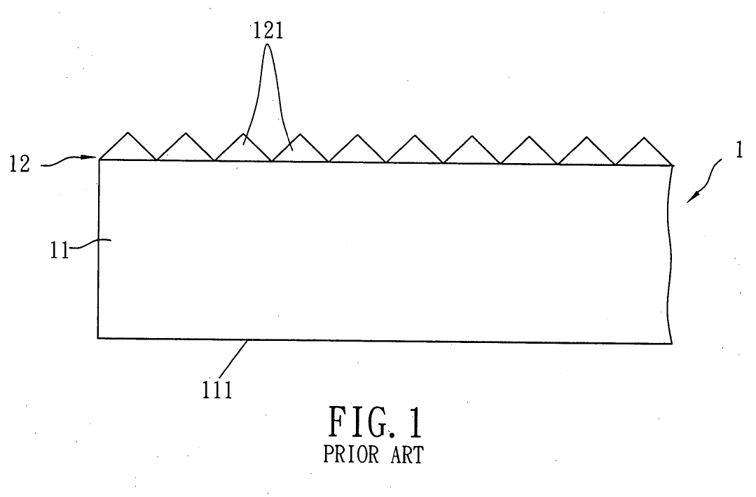

### DETAILED DESCRIPTION OF THE PREFERRED EMBODIMENT

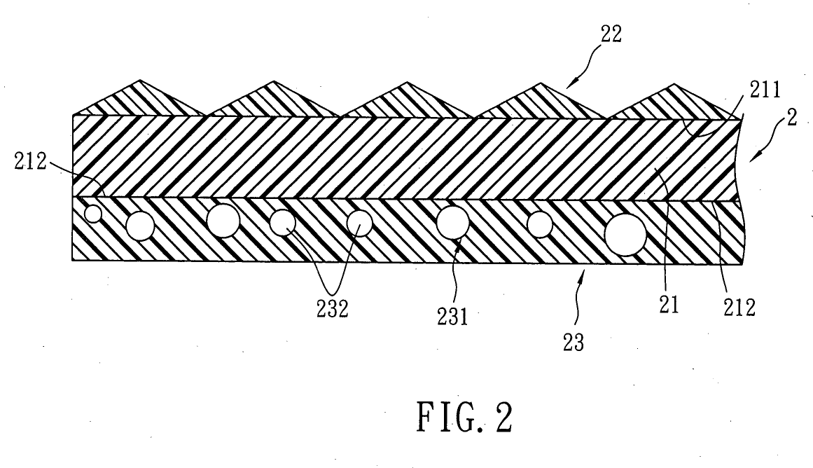

Referring to FIG. 2, the preferred embodiment of an optical sheet 2 according to the present invention includes a substrate 21 having a first surface 211 and a second surface 212 opposite to the first surface 211, a light gathering layer 22 formed on the first surface 211 of the substrate 21, and an light diffusion layer 23 formed on the second surface 212 of the substrate 21.

The thickness of the substrate 21 is determined according to the requirement for a desired optical product to be manufactured. Preferably, the substrate 21 has a thickness ranging from 50 μm to 150 μm. In addition, the substrate 21 may be made from any suitable material known in art, such as glass and a plastic material. Non-limiting examples of the plastic material suitable for making the substrate 21 include polyester resin, such as polyethylene terephthalate (PET) resin, polyacrylate resin, such as polymethylmethacrylate (PMMA) resin, polyolefinresin, such as polyethylene (PE) resin and polypropylene (PP) resin, polyimide resin, polycarbonate resin, polyurethane (PU) resin, triacetate cellulose, and mixtures thereof. Preferably, the substrate 21 is made from the plastic material selected from the group consisting of polyethylene terephthalate (PET) resin, polymethyl methacrylate (PMMA) resin, triacetate cellulose, and mixtures thereof.

The light gathering layer 22 may be formed on the first surface 211 of the substrate 21 by applying a composition including a resin, a photoinitiator, and a cross-linking agent to the first surface 211 of the substrate 21. Preferably, the light gathering layer 22 has a thickness ranging from 5 μm to 100 μm, and a refractive index ranging from 1.3 to 1.8. The resin used in the composition for forming the light gathering layer 22 can be any suitable material known in art. Non-limiting examples of the resin include polyester resin, polyacrylate resin, polycarbonate resin, and mixtures thereof. The photoinitiator used in the composition for forming the light gathering layer 22 can be any suitable material known in art, which is capable of producing free radicals when irradiated, and initiating polymerization through transfer of the free radicals. A non-limiting example of the photoinitiator is benzophenone. The cross-linking agent used in the composition for forming the light gathering layer 22 can be any suitable material known in art. A non-limiting example of the cross-linking agent includes methacylate resin having one or more functional groups. Preferably, the cross-linking agent is multi-functional methacrylate resin capable of raising the glass transition temperature of the light gathering layer 22. In addition, the composition for forming the light gathering layer 22 may further include other additives, such as inorganic fillers, a leveling agent, an anti-foaming agent, and an anti-static agent.

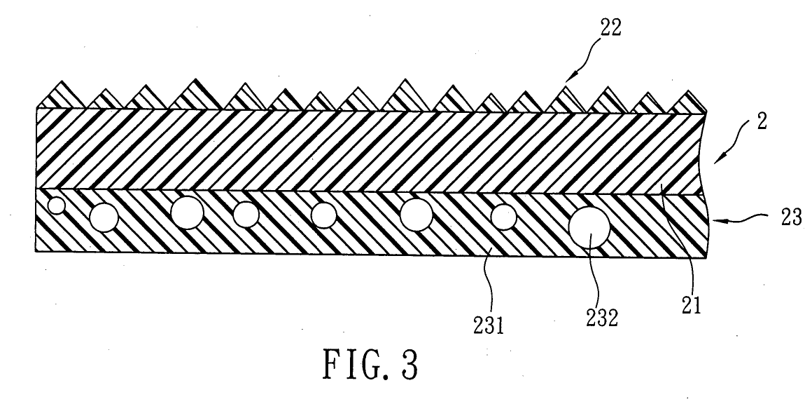

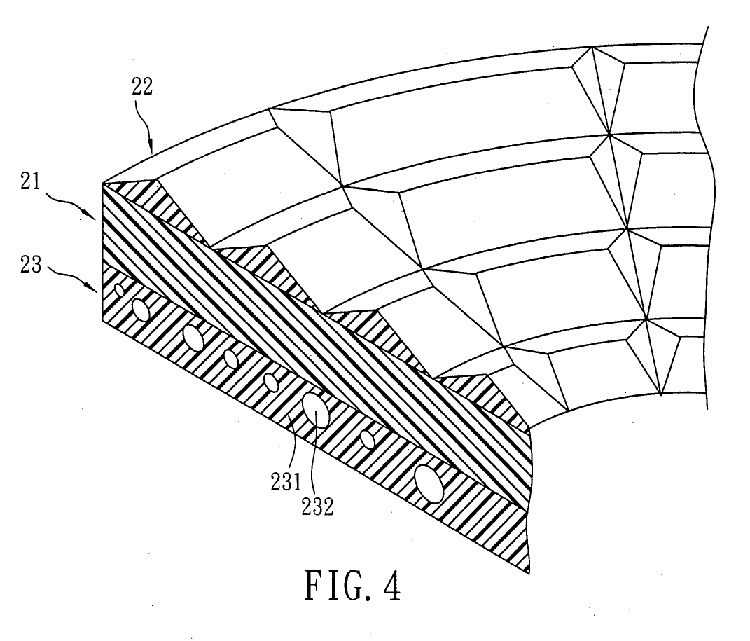

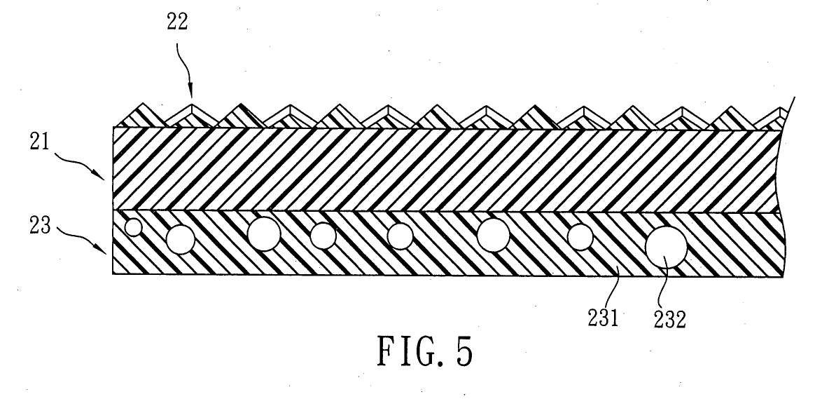

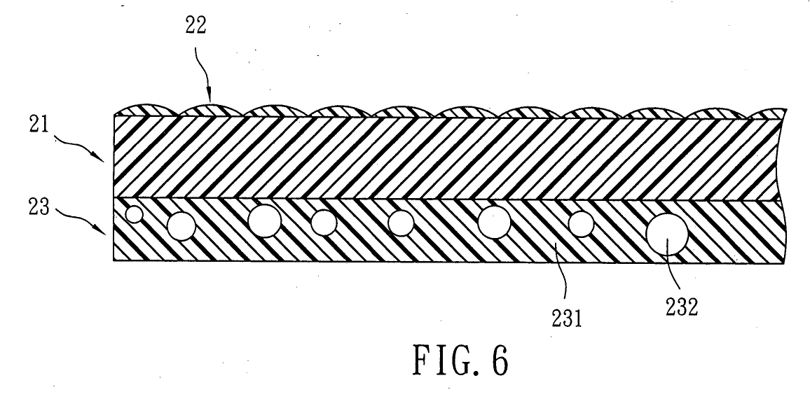

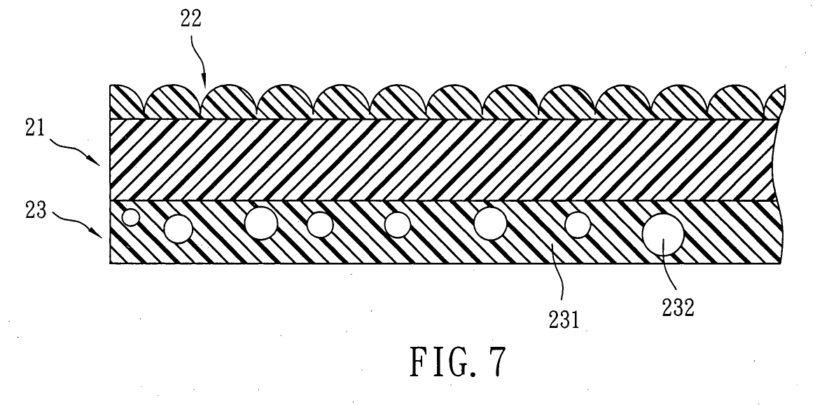

The light gathering layer 22 has at least one microstructure. Preferably, the microstructure of the light gathering layer 22 is selected from the group consisting of a regular prismatic pattern (see FIG. 2), an irregular prismatic pattern (see FIG. 3), an annular prismatic pattern (see FIG. 4), a cube-corner pattern (see FIG. 5), a bead-like pattern (see FIG. 7) and a lens-like pattern (see FIG. 6). More preferably, the microstructure of the light gathering layer 22 is a regular prismatic pattern shown in FIG. 2, or a beak-like pattern (not shown) The light diffusion layer 23 is formed on the second surface 212 of the substrate 21 through application of a composition including a polymeric resin to the second surface 212 of the substrate 21. The polymeric resin suitable for use in the composition for forming the light diffusion layer 23 may include a thermosetting resin or an ultraviolet (UV) curable resin. Preferably, the polymeric resin is an acrylic UV curable resin. Non-limiting examples of the acrylic UV curable resin include methacrylate resin, urethane acrylate resin, polyester acrylate, epoxy acrylate, and mixtures thereof. Preferably, the acrylic UV curable resin is methacrylate resin. In addition, the acrylic UV curable resin may have one or more functional groups. Preferably, the acrylic UV curable resin has multiple functional groups.

Preferably, the polymeric resin 231 included in the light diffusion layer 23 has a plurality of bubbles 232 mixed therein for scattering a light beam passing through the polymeric resin 231. In this case, the composition for forming the light diffusion layer 23 further includes a blowing agent. The blowing agent used in the composition for forming the light diffusion layer 23 can produce an inert gas through heating or UV-irradiating, which results in formation of the bubbles 232 mixed in the polymeric resin 231. The bubbles 232 may have sizes different from each other. A non-limiting example of the blowing agent is sodium carbonate (Na₂CO₃).

In the formation of the light diffusion layer 23 of this invention, when the initiating process (such as heating or UV-irradiating) of foaming the polymeric resin 231 with the blowing agent is the same as that of curing the resin, foaming of the polymeric resin 231 with the blowing agent can be conducted concurrently with curing of the polymeric resin 231. On the other hand, when foaming of the polymeric resin 231 with the blowing agent and curing of the polymeric resin 231 are initiated by different processes, for example, the former being initiated by heating, the latter being initiated by UV-irradiating, foaming of the polymeric resin 231 with the blowing agent is conducted first, followed by curing of the polymeric resin 231.

### EXAMPLES AND COMPARATIVE EXAMPLES

Preparation of a First Colloidal Solution for Forming the Light Diffusion Layer 23

50% by weight of 2-phenoxyethyl acrylate (commercially available from Eternal Co., R.O.C., trademark: EM210®) was mixed with 50% by weight of aliphatic polyurethane hexapropionate (commercially available from Eternal Co., R.O.C., trademark: 6145-100®) so as to form a polymeric resin matrix. 0.5% by weight of sodium carbonate (Na₂CO₃, commercially available from Merck Co., U.S.A.), based on 100% by weight of the polymeric resin matrix, was added to the polymeric resin matrix with stirring so as to form the first colloidal solution for the light diffusion layer 23.

Preparation of a Second Colloidal Solution for Forming the Light Gathering Layer 22

50% by weight of 2-phenoxyethyl acrylate (commercially available from Eternal Co., R.O.C., trademark: EM210®) was mixed with 49% by weight of aliphatic polyurethane hexapropionate (commercially available from Eternal Co., R.O.C., trademark: 6145-100®), and 1% by weight of benzophenone (photoinitiator, commercially available from Double bond, trademark: Chivacure®) with stirring so as to form the second colloidal solution for the light gathering layer 22.

### COMPARATIVE EXAMPLE 1

Optical Sheet Includes the Light Diffusion Layer 23 on a Transparent Substrate 21

The first colloidal solution thus obtained was applied to the transparent substrate 21 made from PET resin (commercially available from Toray company, Japan, trademark: U34®), followed by air-drying the transparent substrate 21 in an oven at a temperature of 100° C. for 20 minutes so as to permit foaming to take place in the applied first colloidal solution. Next, the transparent substrate 21 was moved out of the oven, followed by irradiating with energy rays so as to form the light diffusion layer 23 on the transparent substrate 21. The energy ray refers to a light source with a wavelength ranging from 200 to 600 nm. Preferably, the energy ray is an ultraviolet ray. The light diffusion layer 23 thus formed includes a plurality of bubbles 232 mixed in the polymeric resin matrix of the light diffusion layer 23 and that have an irregular distribution of volumes.

### COMPARATIVE EXAMPLE 2

Optical Sheet Includes the Light Gathering Layer 22 on a Transparent Substrate 21

The second colloidal solution thus formed was applied to the transparent substrate 21 made from PET resin (commercially available from Toray company, Japan, trademark: U34®) . A mold with a pattern was pressed to the applied second colloidal solution so as to transfer-print the pattern from the mold to the applied second colloidal solution, followed by curing the applied second colloidal solution on the transparent substrate 21 using UV-irradiation. The mold was then removed so as to obtain the optical sheet.

### EXAMPLE 1

The first colloidal solution thus formed was applied to a bottom surface 212 of a transparent substrate 21 made from PET resin (commercially available from Toray company, Japan, trademark: U34®), followed by air-drying the transparent substrate 21 in an oven at a temperature of 100° C. for 20 minutes so as to permit foaming to take place in the applied first colloidal solution. Next, the transparent substrate 21 was moved out of the oven, followed by irradiating with UV rays so as to form the light diffusion layer 23 on the bottom surface 212 of the transparent substrate 21. The light diffusion layer 23 thus formed includes a plurality of bubbles 232 that are mixed in the polymeric resin matrix of the light diffusion layer 23 and that have irregular sizes.

The second colloidal solution thus formed was subsequently applied to a top surface 211 of the substrate 21 opposite to the light diffusion layer 23. A mold with a pattern was pressed to the applied second colloidal solution so as to transfer-print the pattern from the mold to the applied second colloidal solution, followed by curing the applied second colloidal solution using UV-irradiation. The mold was then removed so as to obtain the optical sheet 2.

Haze and diffusivity of the transparent substrate, the optical sheet of comparative example 1, the optical sheet of comparative example 2, and the optical sheet of example 1 were tested using NDH 2000 instrument (commercially available from NIPPON DENSHOKU Co., Japan). The test results are shown in Table 1.

TABLE 1

| Specimen | Haze | Diffusivity (Dfs) |
|---|---|---|
| The transparent | 0.5 | 0.5 |
| substrate | | |
| The optical sheet of | 25 | 20 |
| comparative example 1 | | |
| The optical sheet of | 94 | 5 |
| comparative example 2 | | |
| The optical sheet of | 97 | 25 |
| example 1 | | |

In view of the foregoing, the optical sheet 2 of this invention has a distinctive structure over the conventional optical sheet. In addition, when the optical sheet 2 of this invention is applied to the LCD, the light beams from a light source and passing through the optical sheet 2 are scattered in the light diffusion layer 23 first and then collimated in the light gathering layer 22, thereby improving light-collimating and light-scattering effects of the optical sheet 2.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. An optical sheet, comprising:
a substrate having a first surface and a second surface opposite to said first surface;
a light gathering layer formed on said first surface of said substrate; and
a light diffusion layer formed on said second surface of said substrate, and comprising a polymeric resin having bubbles mixed therein.

2. The optical sheet of claim 1, wherein said light gathering layer has at least one microstructure.

3. The optical sheet of claim 2, wherein the microstructure is selected from the group consisting of a regular prismatic pattern, an irregular prismatic pattern, an annular prismatic pattern, a cube-corner pattern, a bead-like pattern and a lens-like pattern.

4. The optical sheet of claim 1, wherein the polymeric resin is a thermosetting resin or an UV curable resin.

5. The optical sheet of claim 4, wherein said UV curable resin is an acrylic UV curable resin selected from the group consisting of methacrylate resin, urethane acrylate resin, polyester acrylate resin, epoxy acrylate resin, and mixtures thereof.

6. The optical sheet of claim 1, wherein said substrate is made from a plastic material selected from the group consisting of polyethylene terephthalate (PET) resin, polymethyl methacrylate (PMMA) resin, polyethylene (PE) resin, polypropylene (PP) resin, polyimide resin, polycarbonate resin, polyurethane (PU) resin, triacetate cellulose, and mixtures thereof.

7. The optical sheet of claim 5, wherein said plastic material is selected from the group consisting of polyethylene terephthalate (PET) resin, polymethyl methacrylate (PMMA) resin, triacetate cellulose, and mixtures thereof.

8. The optic sheet of claim 1, wherein said light gathering layer is made from a resin selected from the group consisting of polyester resin, polyacrylate resin, polycarbonate resin, and mixtures thereof.
